(19) United States
(12) Patent Application Publication
(10) Pub. No.: US 2025/0183035 A1
(43) Pub. Date: Jun. 5, 2025

(54) METHODS FOR MANUFACTURING POWER SEMICONDUCTOR DEVICES AND POWER SEMICONDUDCTOR STRUCTURES

(71) Applicant: SEMICONDUCTOR COMPONENTS INDUSTRIES, LLC, Scottsdale, AZ (US)

(72) Inventor: Alexander Viktorovich BOLOTNIKOV, Niskayuna, NY (US)

(73) Assignee: SEMICONDUCTOR COMPONENTS INDUSTRIES, LLC, Scottsdale, AZ (US)

(21) Appl. No.: 18/529,657

(22) Filed: Dec. 5, 2023

(51) Int. Cl. H01L 21/033; H01L 21/04; H01L 21/266; H01L 21/308; H01L 29/10; H01L 29/16; H01L 29/423; H01L 29/66

(52) U.S. Cl. CPC H01L 21/0337; H10D 12/031; H10D 62/393; H10D 62/8325; H10D 64/311; H10D 64/513; H01L 21/0465; H01L 21/0475; H01L 21/266; H01L 21/3086

(57) ABSTRACT

A method of manufacturing a semiconductor device includes providing a body of semiconductor material including a substrate and a semiconductor region over the substrate. The method includes providing a spacer over the semiconductor region. The method includes providing a first feature as part of the body of semiconductor material self-aligned to a first side wall of the spacer and providing a second feature as part of the body of semiconductor material self-aligned to a second side wall of the pacer. A portion of the semiconductor region is laterally interposed between the first feature and the second feature, the first feature and the second feature can be doped regions or recesses, and the portion of the semiconductor region laterally interposed between the first feature and the second feature comprises a channel region of a JFET semiconductor device or a JFET region of an insulated gate field effect transistor device.

### CROSS-REFERENCE TO RELATED APPLICATIONS

Not applicable.

### TECHNICAL FIELD

The present disclosure relates, in general, to electronics and, more particularly, to semiconductor device structures and methods of forming semiconductor devices.

### BACKGROUND

Silicon Carbide (SiC) power semiconductor devices, such as SiC MOSFETs and SiC JFETs, have several advantageous features in comparison to traditional silicon-based devices. For example, SiC power semiconductor devices are better suited for certain high-power applications because SiC power semiconductor devices are capable of handling high voltages and high operating temperatures. Further, SiC power semiconductor have a low drain-to-source on-resistance (RDSON), (when designed for the same blocking voltages as Si power devices) and fast switching with low power losses, resulting in highly efficient operation.

Some progress has been made in improving the performance of SiC power semiconductor devices by, for example, shrinking the cell pitch to improve on-resistance, by using trench gate structures to improve MOSFET channel mobility, and by using charge-balance or super-junction (SJ) structures to reduce drift region resistance. However, implementing these techniques as well as others has been a challenge because there are challenges with trade-offs with other performance characteristics that are adversely affected by these techniques, such as breakdown voltage (BVDSS). In addition, the required cell pitch dimensions for next generation SiC power semiconductor devices exceed typical tolerances of current wafer processing equipment and alternative equipment is cost prohibitive.

Accordingly, structures and methods are needed that, among other things, facilitate cost effective manufacture of power semiconductor devices, such as SiC power semiconductor devices. It would be beneficial for such structures and methods to be readily manufacturable and to minimize any effects on other performance characteristics.

### BRIEF DESCRIPTION OF THE DRAWINGS

FIGS. 1, 2, 3, 4, and 5 illustrate partial cross-sectional views of a semiconductor device at various steps in manufacture in accordance with the present description;

FIG. 6 illustrates a partial top plan view of a semiconductor device in accordance with the present description;

FIG. 7 illustrates a partial cross-sectional view of the semiconductor device of FIG. 6 taken along reference line 7′-7′;

FIG. 8 illustrates a partial cross-sectional view of the semiconductor device of FIG. 6 taken along reference line 8′-8′;

FIGS. 9, 10, 11, 12, and 13 illustrate partial cross-sectional views of the semiconductor device of FIGS. 6-8 at various steps in manufacture in accordance with the present description;

FIG. 14A illustrates a partial cross-sectional view of the semiconductor device of FIG. 6 at a step in manufacture taken along reference 7′-7′ of FIG. 6;

FIG. 14B illustrates a partial cross-sectional view of the semiconductor device of FIG. 6 at a step in manufacture taken along reference 7′-7′ of FIG. 6;

FIG. 15 graphically illustrates drain current density (J_{D} in Amps/cm²) versus gate to source voltage (V_{DS} in Volts) for the semiconductor device of FIGS. 6-8 compared to a previous semiconductor device;

FIG. 16 graphically illustrates drain current density (J_{D} in Amps/cm²) versus drain to source voltage (V_{DS} in Volts) for the semiconductor device of FIGS. 6-8 compared to a previous semiconductor device;

FIGS. 17, 18, 19, 20, 21, 22, and 23 illustrate partial cross-sectional views of a semiconductor device at various steps in manufacture in accordance with the present description;

FIGS. 24, 25, and 26 illustrate partial cross-sectional views of a semiconductor device at various steps in manufacture in accordance with the present description;

FIG. 27 illustrates a partial cross-sectional view of a semiconductor device manufactured in accordance with the method of FIGS. 24 and 25 after further processing in accordance with the present description;

FIG. 28 illustrates a partial cross-sectional view of a semiconductor device manufactured in accordance with the method FIGS. 24-26 after further processing in accordance with the present description;

FIG. 29, illustrates a partial cross-sectional view of a semiconductor device manufactured in accordance with FIGS. 24-26 after further processing in accordance with the present description; and

FIGS. 30, 31, 32, and 33 illustrates partial cross-section views of a semiconductor device at various steps in manufacture in accordance with the present description.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

For simplicity and clarity of the illustration, elements in the figures are not necessarily drawn to scale, and the same reference numbers in different figures denote the same elements. Additionally, descriptions and details of well-known steps and elements are omitted for simplicity of the description.

For clarity of the drawings, certain regions of device structures, such as doped regions or dielectric regions, trenches, or contacts may be illustrated as having generally straight-line edges and precise angular corners. However, those skilled in the art understand that, due to the diffusion and activation of dopants or formation of layers, the edges of such regions generally may not be straight lines and that the corners may not be precise angles.

Although the semiconductor devices are explained herein as certain N-type conductivity regions and certain P-type conductivity regions, a person of ordinary skill in the art understands that the conductivity types can be reversed and are also possible in accordance with the present description, considering any necessary polarity reversal of voltages, inversion of transistor type and/or current direction, etc.

In addition, the terminology used herein is for the purpose of describing particular examples only and is not intended to be limiting of the disclosure. As used herein, the singular forms are intended to include the plural forms as well, unless the context clearly indicates otherwise.

As used herein, “current-carrying electrode” means an element of a device that carries current through the device, such as a source or a drain of an MOS transistor, an emitter or a collector of a bipolar transistor, or a cathode or anode of a diode, and a “control electrode” means an element of the device that controls current through the device, such as a gate of a MOS transistor or a base of a bipolar transistor.

The term “major surface” when used in conjunction with a semiconductor region, wafer, or substrate means the surface of the semiconductor region, wafer, or substrate that forms an interface with another material, such as a dielectric, an insulator, a conductor, or a polycrystalline semiconductor. The major surface can have a topography that changes in the x, y and z directions.

The terms “comprises”, “comprising”, “includes”, “including”, “has”, “have” and/or “having” when used in this description, are open ended terms that specify the presence of stated features, numbers, steps, operations, elements, and/or components, but do not preclude the presence or addition of one or more other features, numbers, steps, operations, elements, components, and/or groups thereof.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

Although the terms “first”, “second”, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present disclosure.

It will be appreciated by one skilled in the art that words, “during”, “while”, and “when” as used herein related to circuit operation are not exact terms that mean an action takes place instantly upon an initiating action but that there may be some small but reasonable delay, such as propagation delay, between the reaction that is initiated by the initial action. Additionally, the term “while” means a certain action occurs at least within some portion of a duration of the initiating action.

The use of word “about”, “approximately”, or “substantially” means a value of an element is expected to be close to a state value or position. However, as is well known in the art there are always minor variances preventing values or positions from being exactly stated.

Unless specified otherwise, as used herein, the word “over” or “on” includes orientations, placements, or relations where the specified elements can be in direct or indirect physical contact.

Unless specified otherwise, as used herein, the word “overlapping” includes orientations, placements, or relations where the specified elements can at least partly or wholly coincide or align in the same or different planes.

It is further understood that the examples illustrated and described hereinafter suitably may have examples and/or may be practiced in the absence of any element that is not specifically disclosed herein.

### DESCRIPTION

In general, the present examples relate to semiconductor device structures and methods of making semiconductor devices, such as SiC power devices, having improved manufacturability and performance. Examples of such SiC power devices include but are not limited to Junction Field Effect Transistor (JFET) devices and Insulated Gate Field Effect Transistor (IGFET) devices, such as Metal-Oxide-Semiconductor Field Effect Transistor (MOSFET) devices. More particularly, structures and methods are described that use spacer structures to form features of the semiconductor device. Such features can include, but are not limited to recesses, doped regions, or deposited materials. In some examples, the features can be the same structure, can be different structures, can be interconnected structures, or can be separated structures.

In some examples, the features are formed self-aligned to opposing sides of the spacer structure and are laterally separated by a distance defined by the spacer structure. In some examples, the recess features can be used to form doped gate regions for JFET devices or isolated gate structures for IGFET devices. In some examples, the doped region features can be used to form gate regions for JFET devices or base regions for IGFET devices.

Among other things, the spacer structures and methods described herein provide a cost-effective way to manufacture power semiconductor devices, such as SiC power devices having reduced cell pitch without having to invest in expensive photolithographic processing equipment. In some examples, the cell pitch can be reduced to less than two (2) microns compared to a pitch of greater than four (4) microns for previous devices. Accordingly, the methods and structures described hereinafter provide semiconductor devices, such SiC power semiconductor devices with improved performance.

In an example, a method of manufacturing a semiconductor device includes providing a body of semiconductor material comprising a top side, a bottom side opposite to the top side, and a first conductivity type. The method includes providing a mask over the top side, the mask comprising a side wall. The method includes providing a conformal layer over the top side and the mask and removing a portion of the conformal layer to provide a first spacer adjoining the side wall of the mask. The method includes removing the mask. The method includes providing a first feature as a first part of the body of semiconductor material self-aligned to a first side of the first spacer and providing a second feature as a second part of the body of semiconductor material self-aligned to a second side of the first spacer, wherein a portion of the body of semiconductor material is laterally interposed between the first feature and the second feature. The method includes removing the first spacer. The portion of the body of semiconductor material laterally interposed between the first feature and the second feature comprises a channel region of a JFET semiconductor device or a JFET region of an insulated gate field effect transistor device. A JFET region can include a current-spreading region.

In an example, a method of manufacturing a power semiconductor device includes providing a body of semiconductor material including a top side, a bottom side opposite to the top side, a SiC semiconductor material, and a first conductivity type. The method includes providing a first spacer over the top side. The method includes providing a first doped region and a second doped region both comprising a second conductivity type opposite the first conductivity type self-aligned to the first spacer, wherein the first doped region and the second doped region are laterally spaced apart to define a channel region between the first doped region and the second doped region.

In an example, a method of manufacturing a semiconductor device includes providing a body of semiconductor material including a substrate, a semiconductor region over the substrate comprising a first conductivity type, a top side, a bottom side opposite to the top side, and a first conductivity type. The method includes providing a first spacer over the top side. The method includes providing a first feature as part of the body of semiconductor material self-aligned to a first side wall of the first spacer and providing a second feature as part of the body of semiconductor material self-aligned to a second side wall of the first spacer. A portion of the semiconductor region is laterally interposed between the first feature and the second feature, the first feature comprises a first doped region or a first recess, the second feature comprises a second doped region or a second recess, and the portion of the semiconductor region laterally interposed between the first feature and the second feature comprises a channel region of a JFET semiconductor device or a JFET region of an insulated gate field effect transistor device.

Other examples are included in the present disclosure. Such examples may be found in the figures, in the claims, or in the description of the present disclosure.

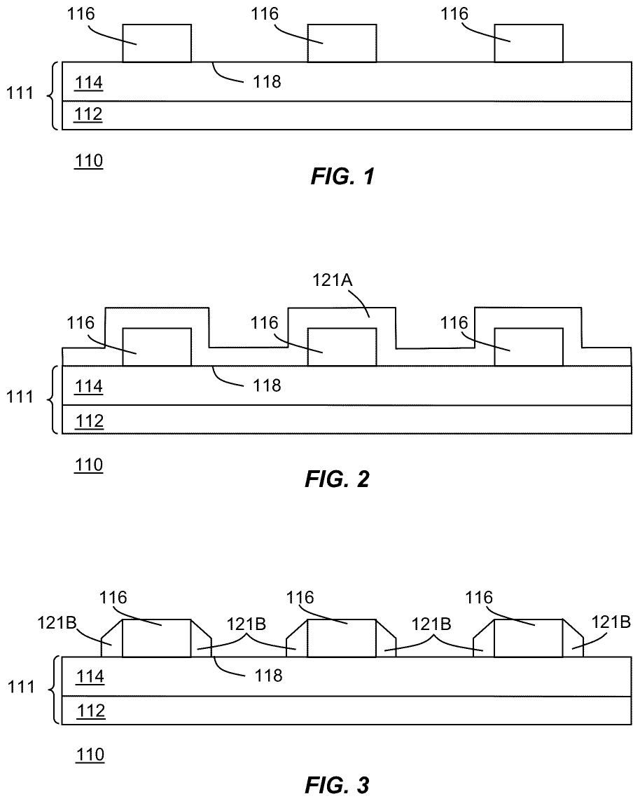

FIGS. 1, 2, 3, 4, and 5 illustrate partial cross-sectional views of a semiconductor device 110 at various steps in manufacture in accordance with the present description. The method described hereinafter can be used to define regions for semiconductor device 110 that were previously limited by conventional lithography techniques for power semiconductor devices, such as SiC power devices.

With reference to FIG. 1, semiconductor device 110 comprises a body of semiconductor material 111, which in some examples, can comprise substrate 112 and semiconductor region 114 provided in or over substrate 112. In the present example, body of semiconductor material 111 includes a top side 118. Body of semiconductor material 111 can also comprise and can be referred to as a region of semiconductor material, a semiconductor workpiece, or a workpiece. In some examples, substrate 112 comprises a semiconductor substrate, such as a silicon or SiC substrate and semiconductor region 114 comprises an epitaxially formed SiC region. In some examples, substrate 112 and semiconductor region 114 are configured for manufacturing a power semiconductor device, such as a SiC power device. In other examples, body of semiconductor material 111 can comprise other semiconductor materials including silicon, IV-IV semiconductor materials (for example, SiGe, SiGeC), or compound semiconductor materials.

A mask 116 is provided adjacent to top side 118 and can comprise an organic material, such as a photoresist or other polymer materials, or inorganic materials, such as hard mask materials including dielectrics. Mask 116 can be provided using photolithographic and etching techniques or using other processes as known to one of ordinary skill in the art.

FIG. 2 illustrates semiconductor device 110 after further processing. In the present example, a conformal layer 121A is provided over top side 118 of body of semiconductor material 111 and mask 116. In some examples, conformal layer 121A comprises a dielectric and can be formed using chemical vapor deposition (CVD) techniques, such as low-pressure CVD (LPCVD), plasma-enhanced CVD (PECVD), or other deposition techniques as known to one of ordinary skill in the art. In some examples, conformal layer 121A comprises an oxide, a nitride, or combinations thereof. The thickness of conformal layer 121A is selected in accordance with a desired lateral spacing between features, which will be provided self-aligned to the spacers subsequently formed from conformal layer 121A. The thickness of conformal layer 121A translates into width 122 of spacers 121B as illustrated in FIG. 4. In some examples, the thickness can be approximately 5000 Angstroms or less.

FIG. 3 illustrates semiconductor device 110 after further processing. In the present example, anisotropic etching can be used to remove portions of conformal layer 121A while leaving other portions of conformal layer 121A as spacers 121B adjoining or along lateral sides of mask 116. Spacers 121B can also be referred to or comprise spacer structures or first spacers. In some examples, dry etching techniques can be used to anisotropically etch conformal layer 121A to provide spacers 121B.

FIG. 4 illustrates semiconductor device 110 after further processing. In the present example, mask 116 is removed leaving spacers 121B adjacent to or over top side 118 of body of semiconductor material 111. As described previously, spacers 121B comprise width 122 set or defined by the thickness of conformal layer 121A. In accordance with the present description, since two spacers 121B are formed per mask 116 (that is, one spacer per lateral side), the pitch or unit cell width of semiconductor device 110 can be reduced approximately two times (2×) compared to conventional masking techniques. In addition, independent control of the mask line and spacing can provide for simultaneous formation of cells comprising two different alternative pitches. This provides an advantageous flexible design feature.

FIG. 5 illustrates semiconductor device 110 after further processing. In the present example, spacers 121B are used to form example features in or over body of semiconductor material 111. The features can include, but are not limited to, doped regions 123A, recesses or recessed regions 123B, or material regions 123C. In some examples, the features are formed self-aligned to two lateral sides of spacers 121B and are laterally separated by a distance determined by width 122 of spacers 121B. In the present example, a portion of body of semiconductor material 111 is laterally interposed between adjacent features.

In some examples, the features for semiconductor device 110 provided using spacers 121B can be the same, can be different, can be interconnected within body of semiconductor material 111, or can be separate or discrete regions within body of semiconductor material 111. In some examples, the discrete regions can be subsequently coupled together using, for example, conductive interconnects.

As will be described in more detail hereinafter, doped regions 123A can be used to form gate regions for JFET devices and body regions for IGFET regions and recessed regions 123B can be used to form gate regions for JFET devices and IGFET regions. In other examples, material regions 123C can be used as device regions or conductive structures, such as interconnects or field plates for semiconductor device 110.

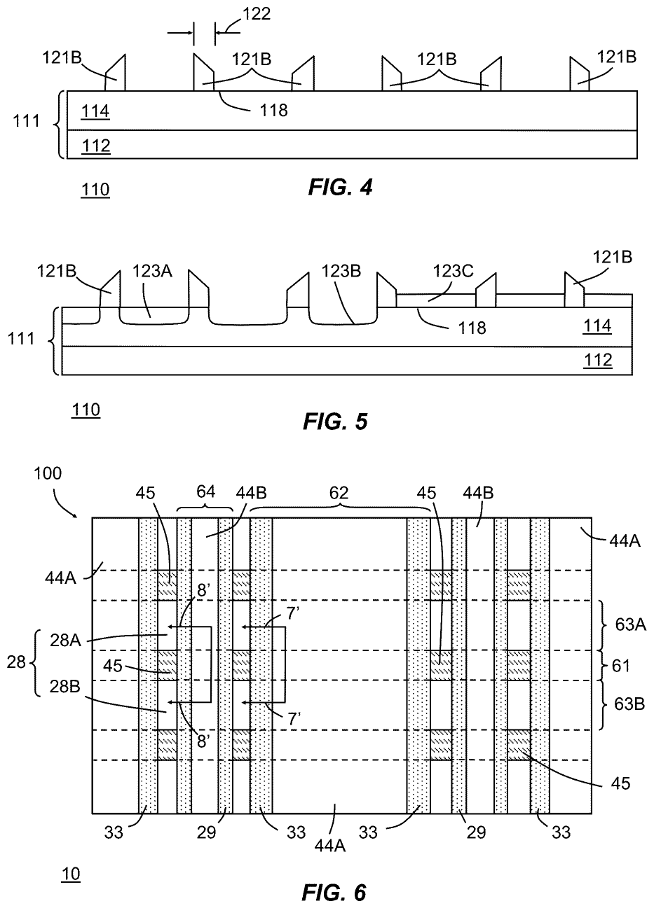

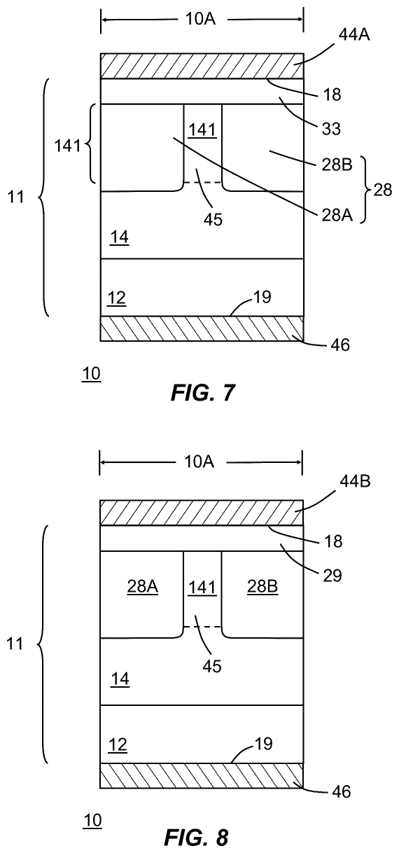

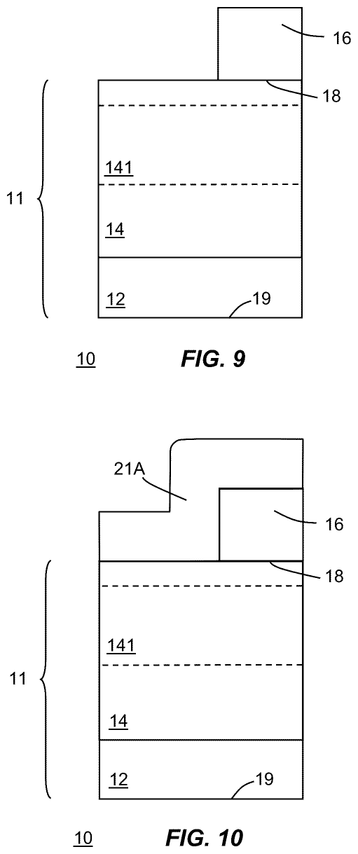

FIG. 6 illustrates a top plan view and FIGS. 7 and 8 illustrate cross-sectional views of a semiconductor device 10 in accordance with the present description. FIG. 7 illustrates a partial cross-sectional view of semiconductor device 10 taken along reference line 7′-7′ of FIG. 6 and FIG. 8 illustrates a partial cross-sectional view of semiconductor device 10 taken along reference line 8′-8′ of FIG. 6. Semiconductor device 10 can also be referred to as or comprise a power semiconductor device, an electronic component, or a JFET device. It is understood that semiconductor device 10 is illustrated as a single or partial cell, and that semiconductor device 10 typically includes many such cells as well as other device elements (for example, additional insulating layers, conductive layers, a gate pad region, terminations, and others). In the present example, semiconductor device 10 has a cell pitch 10A of about 1.4 microns.

In the present example, semiconductor device 10 comprises a high voltage SiC JFET power device and will be described as a normally-on device. It is understood that the present description can be used to form normally-off devices, devices having different voltage ratings, as well as other types of semiconductor devices. In the present example, spacers are used to form features for semiconductor device 10 including gate regions. The spacers facilitate forming the gate regions separated by a channel with a reduced lateral dimension in a cost-effective way that exceeds present capabilities of typical manufacturing equipment used for power semiconductor devices. This capability improves the performance of the semiconductor device.

In the present example, semiconductor device 10 comprises body of semiconductor material 11, which can comprise substrate 12 and semiconductor region 14. In some examples, substrate 12 comprises a starting substrate and semiconductor region 14 comprises an epitaxial region or layer formed over a top side of substrate 12. In the present example, semiconductor region 14 defines a top side 18 of body of semiconductor material 11 and substrate 12 defines a bottom side 19 of body of semiconductor material 11.

In some examples, substrate 12 comprises a SiC substrate, a first conductivity type (for example, N-type conductivity), and low resistivity (for example, 15 to 28 milli-Ohm-cm). In an example 650 volt device, semiconductor region 14 comprises SiC, can comprise the first conductivity type (for example, N-type conductivity), a dopant concentration in a range from about 2.0×10¹⁶ atoms/cm³ to about 5.0×10¹⁶ atoms/cm³, and a thickness in a range from about 4.0 microns to about 6.0 microns. The thickness, dopant concentrations, or dopant profiles of semiconductor region 14 can be adjusted in accordance with desired breakdown voltage characteristics for semiconductor device 10. Semiconductor region 14 can be formed using epitaxial growth techniques and can be doped in-situ during the epitaxial growth process. It is understood that semiconductor region 14 can be formed using other doping or deposition techniques as known to one of ordinary skill in the art. In other examples, body of semiconductor material 11 can comprise other semiconductor materials including silicon, IV-IV semiconductor materials (for example, SiGe, SiGeC), or compound semiconductor materials.

In some examples, body of semiconductor material 11 comprises a doped region 141 comprising the first conductivity type (for example, N-type conductivity) within a portion of semiconductor region 14. In some examples, doped region 141 has a higher dopant concentration than semiconductor region 14 and is configured in the present example to provide channel 45 of semiconductor device 10. In some examples, the dopant concentration of doped region 141 can be in a range from about 1.0×10¹⁷ to about 1.0×10¹⁸ atoms/cm³. Dopant for doped region can be provided as part of the epitaxial growth process for semiconductor region 14 or by providing additional dopant into semiconductor region 14 after semiconductor region 14 is formed.

Semiconductor device 10 comprises a gate structure or gate region 28 that includes doped region 28A and doped region 28B within body of semiconductor material 11. A portion of semiconductor region 14 is laterally interposed between doped region 28A and doped region 28B. This portion of doped region 141 defines a channel 45 for semiconductor device 10. Doped region 28A can also be referred to as a first feature and doped region 28B can also be referred to as a second feature. In this example, the first feature (for example, doped region 28A) and the second feature (for example, doped region 28B) are the same type of feature. As will be described in more detail later, doped region 28A and doped region 28B are formed within body of semiconductor material 11 self-aligned to a spacer in accordance with the present description. Channel 45 can also be referred to as or comprise a channel region or a JFET channel. In accordance with the present description, by using the spacer, channel 45 is provided with a reduced width compared to prior devices that used conventional photolithographic techniques for power semiconductor devices. Semiconductor device 10 is an example of a semiconductor device comprising a spacer-defined gate region 28 and a spacer-defined channel 45. In some embodiments the bottom portion of channel 45 can be aligned with or can be lower than lower boundary of the regions 28A and 28B.

In some examples, doped region 28A and doped region 28B comprise a second conductivity type (for example, P-type conductivity) and an average dopant concentration in a range from about 5.0×10¹⁷ to about 5.0×10¹⁸ atoms/cm³. In some examples, the dopant concentration of doped region 28A and doped region 28B proximate to top side 18 of body of semiconductor material 11 can be higher to provide for ohmic contact. In some examples, doped region 28A and doped region 28B can be provided within body of semiconductor material 11 using ion implantation and diffusion/anneal techniques.

Semiconductor device 10 further comprises doped region(s) 33 in portions of body of semiconductor material 11 and doped region(s) 29 in other portions of body of semiconductor material 11. In the present example, doped region 33 comprises the first conductivity type (for example, N-type conductivity) and is configured as a source contact region. In some examples, doped region 33 can be formed using ion implantation with a phosphorous or nitrogen dopant source. In some examples, doped region 33 can have a peak dopant concentration greater than about 1.5×10¹⁹ atoms/cm³ and is an example of a third doped region.

In the present example, doped region 29 comprises the second conductivity type (for example, P-type conductivity) and is configured as a gate contact region. In some examples, doped region 29 can be formed using ion implantation with an aluminum dopant source. In some examples, doped region 29 can have a peak dopant concentration greater than about 1.5.0×10¹⁹ atoms/cm³ and is an example of a fourth doped region.

Semiconductor device 10 further comprises conductor 44A, conductor 44B, and conductor 46. In the present example, conductor 44A is formed over first portions of top side 18 of body of semiconductor material 11 and is coupled to doped region 33. Conductor 44B is formed over second portions of top side 18 of body of semiconductor material 11 and is coupled to doped region 29. In some examples, conductor 44A and conductor 44B can comprise nickel, nickel silicide, titanium, other conductive materials or combination of thereof.

In some examples, conductor 46 is provided over bottom side 19 of body of semiconductor material 11 and is coupled to substrate 12. In some examples, conductor 46 can comprise a plurality of metal layers, such as nickel-titanium-nickel-silver, chrome-nickel-gold, or other conductive materials. Conductors 44A, 44B, and 46 can be formed using deposition processes, such as evaporation, sputtering, or other techniques as known to one of ordinary skill in the art. Photolithographic and etch techniques can be used to provide conductors 44A and 44B after the deposition process. In some examples, conductor 44A can be referred to a current carrying electrode or a source electrode, conductor 46 can be referred to as a current carrying electrode or a drain electrode, and conductor 44B can be referred to as a control electrode or a gate electrode. With an appropriate gate voltage applied to conductor 44B and an appropriate voltage applied between conductor 44A and conductor 46, current flow in channel 45 can be controlled.

With reference now to FIG. 6, an example cell layout 100 for semiconductor device 10 is described. It is understood that cell layout 100 is an example configuration for semiconductor device 10 and that other configurations can be used in accordance with the present description. In the present example, cell layout 100 includes channel 45 configured as a first elongate stripe 61 and doped region 33 is configured as a second elongate stripe 62, which is generally orthogonal or generally perpendicular to first elongate stipe 61 in the top plan view. In the present example, doped region 28A is configured as an elongate stripe 63A and doped region 28B is configured as an elongate stripe 63B. Elongate stripes 63A and 63B are examples of a gate region comprising third elongate stripes that are generally parallel to first elongate stripe 61. In the present example, doped region 29 is configured as a fourth elongate stripe 64 generally parallel to second elongate stripe 62.

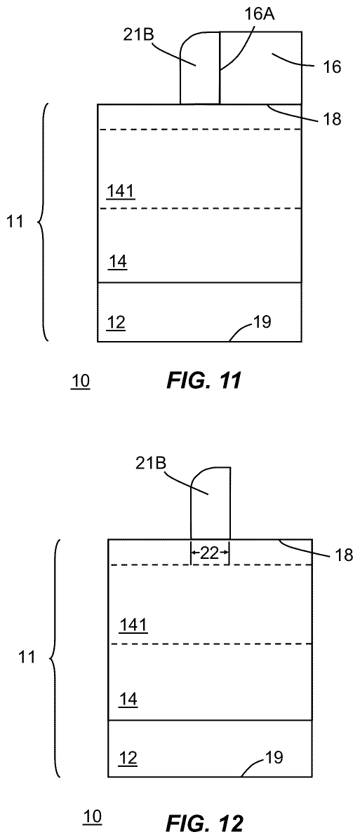

FIGS. 9, 10, 11, 12, 13, 14A, and 14B illustrate partial cross-sectional views of semiconductor device 10 at various steps in an example method of manufacture. In the present example, FIG. 9 illustrates semiconductor device 10 at an earlier step in manufacture where body of semiconductor material 11 is provided, including substrate 12 and semiconductor region 14. Substrate 12, semiconductor region 14, and doped region 141 can comprise materials and characteristics as described previously. In the present example, mask 16 is provided over top side 18 of body of semiconductor material 11. In some examples, mask 16 can comprise an organic material, such as a photoresist or other polymer materials, or inorganic materials, such as hard mask materials including conductors or dielectrics. Mask 16 can be provided using photolithographic and etching techniques or using other processes as known to one of ordinary skill in the art. In some examples, mask 16 has a thickness in a range from about 1000 Angstroms to about 4 microns. The width of mask 16 is also selected based on the desired pitch or separation between adjacent unit cells within semiconductor device 10. In some examples, the width of each portion of mask 16 is the same. In other examples, the width of mask 16 can vary according to design requirements.

FIG. 10 illustrates semiconductor device 10 after further processing. In the present example, conformal layer 21A is provided over top side 18 of body of semiconductor material 11 and mask 16. In some examples, conformal layer 21A comprises a dielectric and can be formed using CVD techniques, such as LPCVD, PECVD, or other deposition techniques as known to one of ordinary skill in the art. In some examples, conformal layer 21A comprises an oxide, a nitride, polysilicon, or combinations thereof. In the present example, the thickness of conformal layer 21A is selected in accordance with a desired lateral spacing between doped region 28A and doped region 28B. More particularly, the thickness of conformal layer 21A translates into width 22 of spacers 21B as illustrated in FIG. 12. In some examples, the thickness can be approximately 5000 Angstroms or less.

FIG. 11 illustrates semiconductor device 10 after further processing. In the present example, anisotropic etching can be used to remove portions of conformal layer 21A while leaving another portion of conformal layer 21A as spacer 21B adjoining or along lateral side 16A of mask 16. Spacer 21B can also be referred to or comprise a spacer structure or a first spacer. In some examples, dry etching techniques can be used to anisotropically etch conformal layer 21A to form spacer 21B. After spacer 21B is formed, mask 16 can be removed leaving spacer 21B adjacent to or over top side 18 of body of semiconductor material 11 as illustrated in FIG. 12.

FIG. 13 illustrates semiconductor device 10 after further processing. In the present example, doped region 28A and doped region 28B are formed within body of semiconductor material 11 self-aligned to spacer 21B. More particularly, doped region 28A is formed self-aligned to first side 21BA of spacer 21B and doped region 28B is formed self-aligned to second side 21BB of spacer 21B. A portion of semiconductor region 14 is interposed between doped region 28A and doped region 28B to provide channel 45. In accordance with the present description, spacer 21B is used to form more than one feature for semiconductor device 10. That is, in some examples, both lateral sides of spacer 21B are used to form features for semiconductor device 10.

In the present example, doped region 28A and doped region 28B comprise the second conductivity type (for example, P-type conductivity) and can be formed using ion implantation and diffusion/anneal techniques. In some examples, ion implantation using an aluminum doping source comprising one or more ion implant energies which range from tens of keV to several MeV and total dose between 2×10¹³ atoms/cm² and 5×10¹⁵ atoms/cm² can be used to form doped region 28A and doped region 28B.

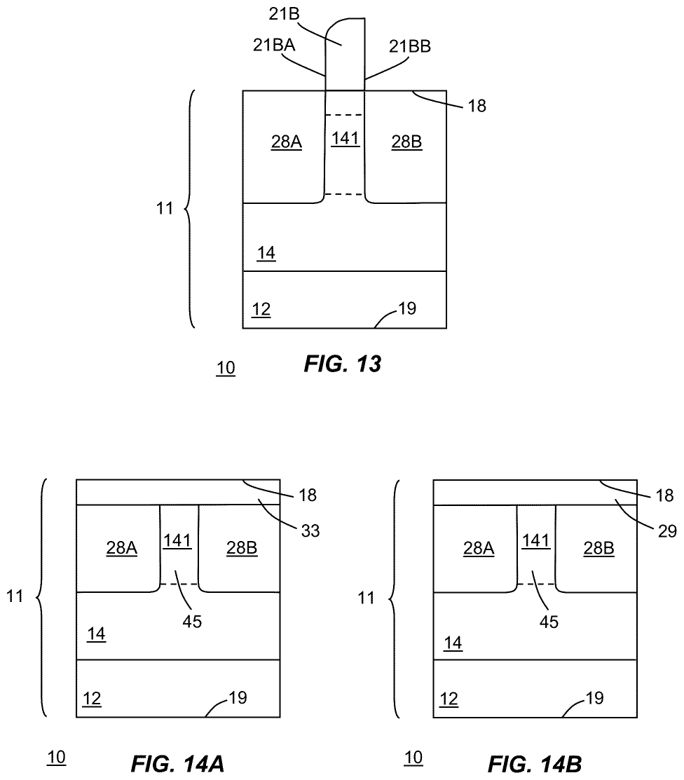

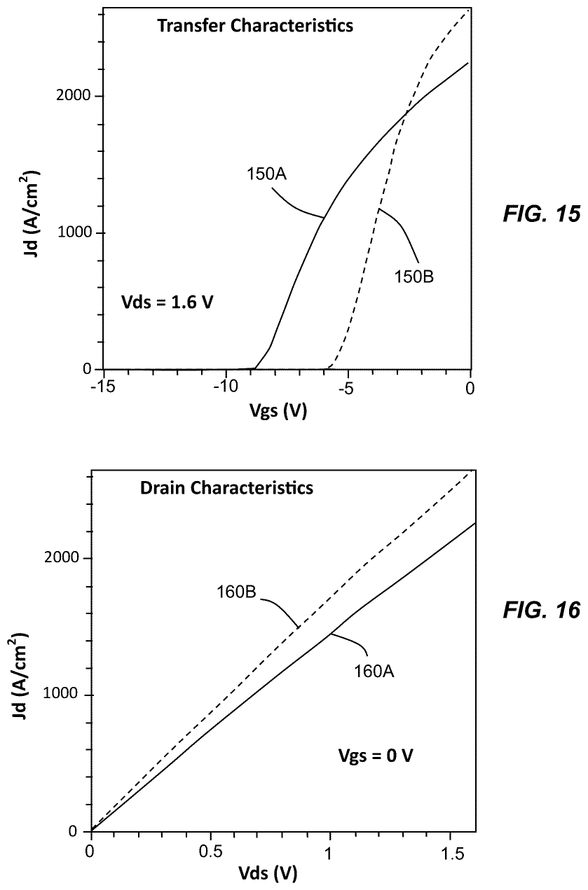

FIG. 14A and FIG. 14B show semiconductor device 10 after further processing to form doped region 33 and doped region 29. FIG. 14A is a cross-sectional view taken along reference line 7′-7′ of FIG. 6 (without conductor 44A) and FIG. 14B is a cross-sectional view taken along reference line 8′-8′ (without conductor 44B). In the present example, doped region 33 is provided in a portion of body of semiconductor material 11 and doped region 29 is provided another portion of body of semiconductor material 11.

In the present example, doped region 33 comprises the first conductivity type (for example, N-type conductivity) and is configured as source contact region. In some examples, doped region 33 can be formed using ion implantation with a phosphorous or nitrogen dopant source. In some examples, doped region 33 can have a dopant concentration greater than about 1.5×10¹⁹ atoms/cm³.

In the present example, doped region 29 comprises the second conductivity type (for example, P-type conductivity) and is configured as a gate contact region. In some examples, doped region 29 can be formed using ion implantation with an aluminum dopant source. In some examples, doped region 29 can have a peak dopant concentration greater than about 1.5×10¹⁹ atoms/cm³. In some examples, after the ion implantation steps and removal of all masking layers (including spacers), body of semiconductor material 11 can be exposed to elevated temperature (for example, above 1000 degrees Celsius when body of semiconductor material 11 comprises SiC) to diffuse and activate the implanted dopants for the various doped regions described. After doped region 33 and doped region 29 are formed, conductors 44A, 44B, and 46 can be provided as previously described.

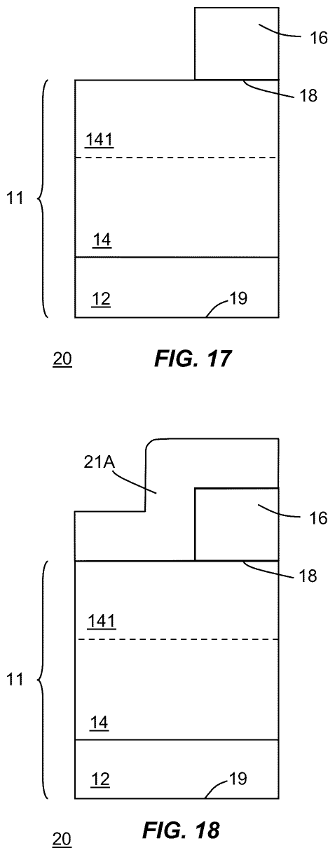

FIG. 15 graphically illustrates transfer characteristics including drain current density (J_{D} in Amps/cm²) versus gate to source voltage (V_{DS} in Volts) for semiconductor device 10 (line 150B) compared to a previous trench JFET (line 150A). As illustrated in FIG. 15, semiconductor device 10 exhibits improved transconductance and lower on resistances (R_{DS(ON)}) for a higher (that is, more positive) threshold voltage compared to the previous device.

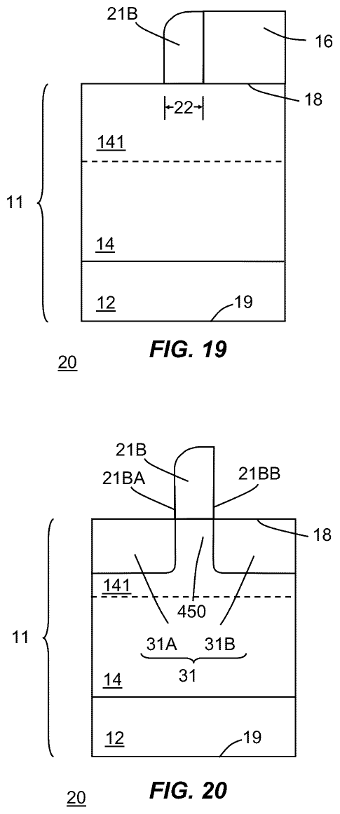

FIG. 16 graphically illustrates the drain characteristics including drain current density (J_{D} in Amps/cm²) versus drain to source voltage (V_{DS} in Volts) for semiconductor device 10 (line 160B) versus a previous trench JFET device (line 160A). As illustrated in FIG. 16, semiconductor 10 exhibits lower R_{DS(ON)} and supports more current for the same voltage compared to the previous device, which translates into, among other things, lower losses.

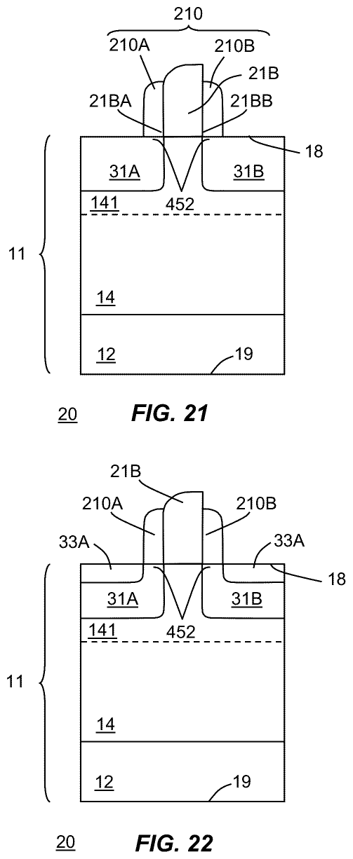

FIGS. 17, 18, 19, 20, 21, 22, and 23 illustrate partial cross-sectional views of a semiconductor device 20 at various steps in manufacture in accordance with the present description. In the present example, semiconductor device 20 comprises a MOSFET device, such as a SiC MOSFET device. The method illustrated in FIGS. 17-23 has some similarity to the method described in FIGS. 9-14B and the similarities will not be repeated here. It is understood that semiconductor device 20 is illustrated as a single or partial cell, and that semiconductor device 20 typically includes many such cells. Semiconductor device 20 is an example of a power semiconductor device that comprises a spacer-defined well region 31 and a spacer-defined JFET region 450.

FIG. 17 illustrates semiconductor device 20 at an earlier step of manufacture where body of semiconductor material 11 is provided, including substrate 12 and semiconductor region 14. In the present example, substrate 12 can be a SiC substrate, can comprise the first conductivity type (for example, N-type conductivity), and can comprise a low resistivity (for example 15 to 28 milli-Ohm-cm). Semiconductor region 14 can comprise SiC, can comprise the first conductivity type (for example, N-type conductivity). In an example 650 volt device, semiconductor region 14 can comprise a dopant concentration in a range from about 2.010¹⁶ atoms/cm³ to about 5.0×10¹⁶ atoms/cm³, and a thickness in a range from about 4 microns to about 6.0 microns. The thickness, dopant concentrations, or dopant profiles of first semiconductor region 14 can be adjusted in accordance with desired breakdown voltage characteristics for semiconductor device 20.

In some examples, body of semiconductor material 11 comprises doped region 141 comprising the first conductivity type (for example, N-type conductivity) within a portion of semiconductor region 14. In some examples, doped region 141 has a higher dopant concentration than semiconductor region 14 and is configured in the present example to provide JFET region 450 of semiconductor device 20. In some examples, the dopant concentration of doped region 141 can be in a range from about 1.0×10¹⁷ to about 1.0×10¹⁸ atoms/cm³. Dopant for doped region can be provided as part of the epitaxial growth process for semiconductor region 14 or by providing additional dopant into semiconductor region 14 after semiconductor region 14 is formed.

In other examples, body of semiconductor material 11 can comprise other semiconductor materials including silicon, IV-IV semiconductor materials (for example, SiGe, SiGeC), or compound semiconductor materials. In the present example, mask 16 is provided over top side 18 of body of semiconductor material 11. In some examples, mask 16 can comprise similar materials and characteristics as described previously.

FIG. 18 illustrates semiconductor device 20 after further processing. In the present example, conformal layer 21A is provided over top side 18 of body of semiconductor material 11 and mask 16. In some examples, conformal layer 21A comprises similar materials and characteristics as described previously. The thickness of conformal layer 21A is selected in accordance with a desired lateral spacing between doped region 31A and doped region 31B, which are illustrated in FIG. 20. More particularly, the thickness of conformal layer 21A translates into width 22 of spacer 21B as illustrated in FIG. 19. In some examples, the thickness can be approximately 5000 Angstroms or less.

FIG. 20 illustrates semiconductor device 20 after further processing. In the present example, doped region 31A and doped region 31B are formed within body of semiconductor material 11 self-aligned to spacer 21B. More particularly, doped region 31A is formed self-aligned to first side 21BA of spacer 21B and doped region 31B is formed self-aligned to second side 21BB of spacer 21B. A portion of semiconductor region 14 is interposed between doped region 31A and doped region 31B, which defines JFET region 450. In accordance with the present description, spacer 21B is used to form more than one feature for semiconductor device 20. That is, both lateral sides of spacer 21B are used to form features for semiconductor device 20.

In the present example, doped region 31A and doped region 31B are part of a body region 31 for semiconductor device 20. In some examples, doped region 31A and doped region 31B are coupled together within body of semiconductor material 11 in a common base configuration. In other examples, doped region 31A and doped region 31B are separated or discrete doped regions in a cellular base configuration. Doped region 31A is an example of a first feature and a first doped region, and doped region 31B is an example of a second feature and a second doped region.

In the present example, doped region 31A and doped region 31B comprise the second conductivity type (for example, P-type conductivity) and can be formed using ion implantation and diffusion/anneal techniques. In some examples, ion implantation using an aluminum doping source with one or more ion implant doses in a range from about 2.0×10¹³ atoms/cm² to about 6.0×10¹⁴ atoms/cm² and an ion implant energy in a range from about 150 keV to about 600 keV can be used to form doped region 31A and doped region 31B. In some examples, doped region 31A and doped region 31B comprise an average dopant concentration in range from about 2.0×10¹⁷ to about 5.0×10¹⁸ atoms/cm³. In some examples, doped region 31A and doped region 31B terminate with semiconductor region 14.

FIG. 21 illustrates semiconductor device 20 after further processing. In the present example, a second spacer structure 210 is provided over top side 18 of body of semiconductor material 11. In some examples, a conformal layer, which can be similar to conformal layer 21A, is first provided over top side 18 and spacer 21B and then anisotropically etched to form second spacer first portion 210A adjacent to first side 21BA of spacer 21B and a second spacer second portion 210B adjacent to second side 21BB of spacer 21B. In the present example, the thickness of the conformal layer for second spacer structure 210 is selected to define channels 452 of semiconductor device 20. In some examples, the conformal layer for second spacer structure 210 has a thickness in a range from about 0.1 microns to about 0.5 microns.

FIG. 22 illustrates semiconductor device 20 after further processing. In the present example, doped regions 33A are formed self-aligned to second spacer first portion 210A and second spacer second portion 210B. In the present example, doped regions 33A comprise the first conductivity type (for example, N-type conductivity), can be formed using ion implantation and anneal process techniques, and can comprise a dopant concentration of about 5.0×10¹⁹ atoms/cm³. Doped regions 33A can also be referred to as or comprise source regions or current carrying regions.

FIG. 23 illustrates semiconductor device 20 after further processing. In the present example, second spacer structure 210 and spacer 21B can be removed and gate dielectric 26 provided overlying channels 452 and JFET region 450 of semiconductor device 20. In some examples, gate dielectric 26 can comprise an oxide or a nitride and can have a thickness in a range from about 200 Angstroms to about 1000 Angstroms. In some examples, gate dielectric 26 can one or more of the following materials: Hf, Al, La, O, N, Si, P, Bi, B, or Li.

In some examples, semiconductor device 20 includes doped regions 36 comprising the second conductivity type (for example, P-type conductivity) type within doped region 31A and doped region 31B. Doped region 36 provides enhanced contact to doped region 31 and can reduce certain parasitic effects. In some examples, after the ion implantation steps and removal of all masking layers (including spacers), body of semiconductor material 11 can be exposed to elevated temperature to diffuse and activate the implanted dopants for the various doped regions described.

Conductor 44A can then be provided over top side 18 of body of semiconductor material 11 and coupled to doped regions 33A and doped region 36. In the present example, conductor 44A can also be referred to as or comprise a source electrode. Conductor 44B can be provided over gate dielectric 26 and conductor 46 can be provided adjacent to bottom side 19 of region of semiconductor material 11. In the present example, conductor 44B can also be referred to as or comprise a gate electrode and conductor 46 can also be referred to or comprise a drain electrode. Gate dielectric 26 and conductor 44B are an example of an insulated gate structure proximate to a first feature (for example, doped region 31A) and to a second feature (for example, doped region 31B). Conductors 44A, 44B, and 46 can comprise the same materials and can be formed using the same processes as described previously, while 44B can also comprise polysilicon. With an appropriate voltage applied to conductor 44B, channels 452 are formed in doped region 31A and doped region 31B allowing current to flow between doped regions 33A and JFET region 450. JFET region 450 is an example of a region for a power semiconductor device laterally interposed between a spacer-defined first feature (for example, doped region 31A) and a spacer-defined second feature (for example, doped region 31B). In accordance with the present description, spacer 21B provides a cost-effective way to provide JFET region 450 that has a smaller lateral width than is achievable using conventional photolithographic techniques for SiC power semiconductor devices.

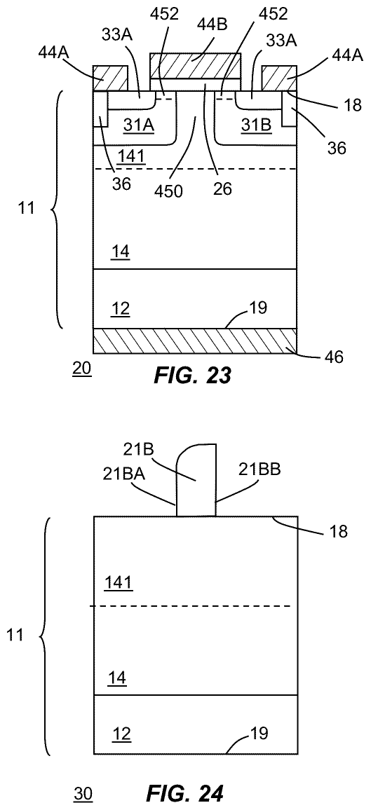

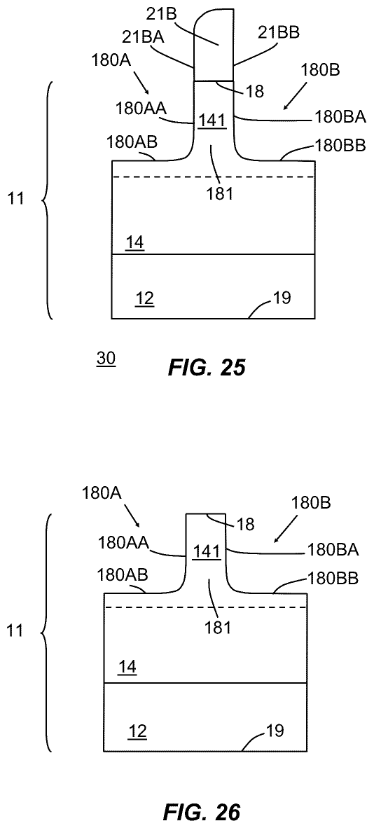

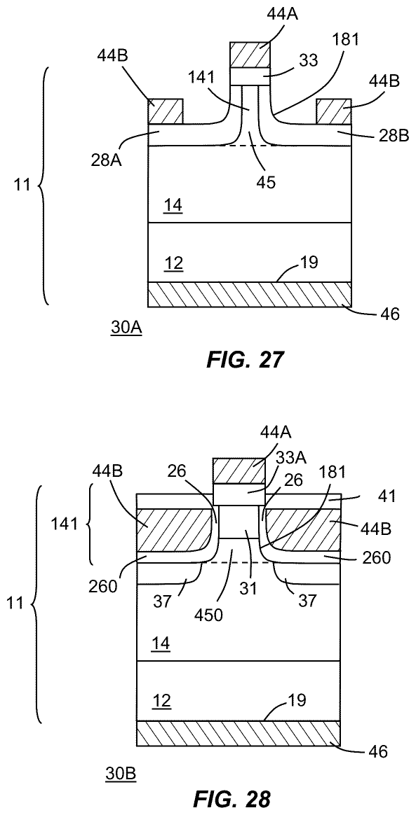

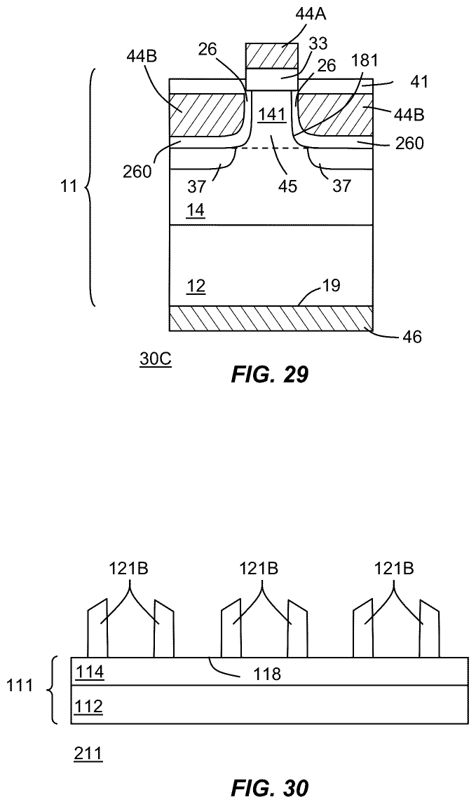

FIGS. 24, 25, and 26 illustrate partial cross-sectional views of a semiconductor device 30 at various steps of manufacture in accordance with the present description. The method described in FIGS. 24-26 can be used to provide a recessed region utilized to form different semiconductor devices including, but not limited to, semiconductor device 30A illustrated in FIG. 27, semiconductor device 30B illustrated in FIG. 28, or semiconductor device 30C illustrated in FIG. 29. It is understood that different doped regions can be provided within body of semiconductor material 11 for some semiconductor devices prior to forming the recessed region depending on specific doping requirements. For example, doped region 31 of semiconductor device 30B illustrated in FIG. 28 can be provided within doped region 141 before the recessed region is formed. In other examples, doped region 31 can be formed after the recessed region is formed.

The method described in FIGS. 24-26 has some similarity to the methods described in FIGS. 9-14B and FIGS. 17-22 and the similarities will not be repeated here. It is understood that semiconductor device 30A, semiconductor device 30B, and semiconductor device 30C are illustrated as single or partial cell, and the semiconductor device 30A, semiconductor device 30B, and semiconductor device 30C typically include many such cells. Semiconductor device 30A, semiconductor device 30B, and semiconductor device 30C are examples of semiconductor devices including power semiconductor devices formed using spacer defined features and regions in accordance with the present description. Such features include but are not limited to recesses and such regions include, but are not limited to JFET channels, JFET regions, or current spreading regions.

FIG. 24 illustrates semiconductor device 30 at an early step in manufacture. In the present example, body of semiconductor material 11 is provided and can include substrate 12 and semiconductor region 14. In the present example, substrate 12 can be a SiC substrate, can comprise the first conductivity type (for example, N-type conductivity) and low resistivity (for example, 15 to 28 milli Ohm-cm). In an example 650 volt device semiconductor region 14 can comprise SiC, the first conductivity type (for example, N-type conductivity), a dopant concentration in a range from about 2.010¹⁶ atoms/cm³ and 5.0×10¹⁶ atoms/cm³, and a thickness in a range from about 4 microns to about 6.0 microns. The thickness, dopant concentrations, or dopant profiles of first semiconductor region 14 can be adjusted in accordance with desired breakdown voltage characteristics for semiconductor device 30 including semiconductor devices 30A, 30B, and 30C.

In some examples, body of semiconductor material 11 comprises doped region 141 comprising the first conductivity type (for example, N-type conductivity) within a portion of semiconductor region 14. In some examples, doped region 141 has a higher dopant concentration than semiconductor region 14. In some examples, the dopant concentration of doped region 141 can be in a range from about 1.0×10¹⁷ to about 1.0×10¹⁸ atoms/cm³. Dopant for doped region can be provided as part of the epitaxial growth process for semiconductor region 14 or by providing additional dopant into semiconductor region 14 after semiconductor region 14 is formed. For semiconductor device 30B of FIG. 28, doped region 31 can be provided within doped region 141 at an early stage of fabrication, for example before spacer 21B is provided.

In other examples, body of semiconductor material 11 can comprise other semiconductor materials including silicon, IV-IV semiconductor materials (for example, SiGe, SiGeC), or compound semiconductor materials. In the present example, spacer 21B is provided over top side 18 of body of semiconductor material 11. In some examples, spacer 21B can comprise similar materials and characteristics, and can formed using similar techniques as described previously.

FIG. 25 illustrates semiconductor device 30 after further processing. In the present example, recess 180A and recess 180B are provided self-aligned to spacer 21B. More particularly, recess 180A is provided self-aligned to first side 21BA of spacer 21B and recess 180B is provided self-aligned to second side 21BB of spacer 21B. In the present example, a portion of semiconductor region 14 is interposed between recess 180A and recess 180B. In accordance with the present description, spacer 21B is used to form more than one feature for semiconductor device 30. That is, both lateral sides of spacer 21B are used to form features.

In the present example, portions of body of semiconductor material 11 are removed to form recess 180A and recess 180B. In some examples, dry etching techniques are used to remove portions body of semiconductor material 11 using an etch chemistry that is selective to the material of body of semiconductor material 11. In some examples, an etch chemistry comprising SF₆/O₂ can be used to form recess 180A and recess 180B. In some examples, recess 180A and recess 180B terminate within doped region 141. In some examples, recess 180A and recess 180B can terminate proximate to the interface between semiconductor region 14 and doped region 141. In some examples, recess 180A and recess 180B can terminate within semiconductor region 14. In some examples, recess 180A comprises recess side wall 180AA and recess lower side 180AB and recess 180B comprises recess side wall 180BA and recess lower side 180BB. It is understood that although not illustrated, recess 180A can comprise another recess side wall opposite to recess side wall 180AA and recess 180B can comprise another recess side wall opposite to recess side wall 180BA. In the present example, the method provides mesa 181 laterally interposed between recess 180A and recess 180B. In some examples, after recess 180A and recess 180B are formed, spacer 21B can be removed to expose top side 18 of body of semiconductor material 11 above mesa 181 as illustrated in FIG. 26. In other examples, spacer 21B can remain place and used to form other features.

FIG. 27 illustrates a partial cross-sectional view of semiconductor device 30A manufactured in accordance with the method described with FIGS. 24-25 after further processing. In the present example, semiconductor device 30A is configured as a SiC trench JFET. In some examples, with spacer 21B remaining in place over top side 18 of body of semiconductor material 11, doped region 28A is formed extending into body of semiconductor material 11 from recess side wall 180AA and recess lower side 180AB of recess 180A and doped region 28B is formed extending inward from recess side wall 180BA and recess lower side 180BB of recess 180B. In present example, doped region 28A and doped region 28B comprise a second conductivity type (for example, P-type conductivity) and a dopant concentration in a range from about 5.0×10¹⁷ to about 5.0×10¹⁸ atoms/cm³. In some examples, doped region 28A and doped region 28B can be provided within body of semiconductor material 11 using angled ion implantation (with spacer 21B in place) and diffusion/anneal techniques. In other examples, dopant for doped region 28A and doped region 28B can be provided using other gaseous phase or deposition processing techniques. In some examples, spacer 21B is removed after doped region 28A and doped region 28B are formed.

In the present example, doped region 28A is an example a third feature comprising a first doped region self-aligned to spacer 21B, and doped region 28B is an example of a fourth feature comprising a second doped region formed self-aligned to spacer 21B. In the present example, spacer 21B is used to form more than two features, or specifically, four features including recess 180A, recess 180B, doped region 28A, and doped region 28B.

Doped region 28A and doped region 28B provide gate regions for semiconductor device 30A, which are laterally separated by channel 45, which can also be referred to as or comprises a JFET channel. In some examples, doped region 33 is provided within mesa 181 proximate to top side 18. In the present example, doped region 33 comprises the first conductivity type (for example, N-type conductivity) and is configured as a source contact region. In some examples, doped region 33 can be formed using ion implantation with a phosphorous or nitrogen dopant source. In some examples, doped region 33 can have a peak dopant concentration greater than about 5×10¹⁹ atoms/cm³. In some examples, after the ion implantation steps and removal of all masking layers (including spacers), body of semiconductor material 11 can be exposed to elevated temperature to diffuse and activate the implanted dopants for the various doped regions described.

In the present example, conductor 44A can be provided coupled to doped region 33, conductor 44B can be provided coupled to doped region 28A and doped region 28B, and conductor 46 can be provided coupled to body of semiconductor material 11 at bottom side 19. In the present example, conductor 44A is configured as a source electrode, conductor 44B is configured as a gate electrode, and conductor 46 is configured as a drain electrode. Conductor 44A, conductor 44B, and conductor 46 can comprise materials and characteristics as described previously and can be formed using processes as described previously. Semiconductor device 30A is an example of a semiconductor device that comprises a spacer-defined recesses 180A and 180B and spacer-defined doped regions 28A and 28B, which define channel 45.

FIG. 28 illustrates a partial cross-sectional view of semiconductor device 30B manufactured in accordance with the method described with FIGS. 24-26 after further processing. In the present example, semiconductor device 30B is configured as a SiC trench MOSFET or FinFET (where mesa 181 is configured as a thin vertical fin).

Semiconductor device 30B comprises doped region 31 formed extending inward from top side 18 into mesa 181. In the present example, doped region 31 terminates within semiconductor region 14 leaving a JFET region 450 below doped region 31. JFET region 450 can also be referred to as or comprise a current spreading region. In the present example, doped region 31 comprises the second conductivity type (for example, P-type conductivity) and can be formed using ion implantation and diffusion/anneal techniques. In some examples, doped region 31 is provided before the formation of spacer 21B. In some examples, when semiconductor region 14 comprises SiC, ion implantation using an aluminum doping source with one or more ion implant having total dose in a range from about 1.0×10¹³ atoms/cm² to about 1.0×10¹³ atoms/cm² and an ion implant energy in a range from about 100 keV to about 400 keV can be used to form doped region 31.

Semiconductor device 30B comprises doped region 33A provided within doped region 31 proximate to top side 18 within mesa 181. In the present example, doped region 33A defines a source region for semiconductor device 30B. Doped region 33A comprises the first conductivity type (for example, N-type conductivity), can be formed using ion implantation and anneal process techniques, and can comprise a dopant concentration of about 5.0×10¹⁹ atoms/cm³. Doped regions 33A can also be referred to as current carrying region.

Semiconductor device 30B comprises gate dielectric 26 along recess side wall 180AA of recess 180A and along recess side wall 180BA of recess 180B. In some examples, a dielectric 260, which can be thicker than gate dielectric 26, is provided along recess lower side 180AB of recess 180A and along recess lower side 180BB of recess 180B. In some examples, gate dielectric 26 can comprise an oxide (for example, silicon dioxide) or a nitride and can have a thickness in a range from about 200 Angstroms to about 1000 Angstroms. In some examples, gate dielectric 26 can one or more of the following materials: Hf, Al, La, O, N, Si, P, Bi, B, or Li. In some examples, dielectric 260 can comprise an oxide and can have a thickness greater than about 1000 Angstroms. In some examples, spacer 21B can remain in place during processing used to provide gate dielectric 26 or dielectric 260, which is an example where spacer 21B is used to form more than two features including recess 180A, recess 180B, gate dielectric 26, and dielectric 260.

In some examples, doped regions 37 can be formed within body of semiconductor material 11 below recess lower side 180AB of recess 180A and below recess lower side 180BB of recess 180B prior to formation of the dielectric 260. In some examples, doped region 37 comprise the second conductivity type (for example, P-type conductivity) and can have similar characteristics and can be formed using similar processes as described for doped region 31. In some examples, after the ion implantation steps and removal of all masking layers (including spacers), body of semiconductor material 11 can be exposed to elevated temperature to diffuse and activate the implanted dopants for the various doped regions described.

In the present example, conductor 44A can be provided coupled to doped region 33A and conductor 46 can be provided coupled to body of semiconductor material 11 at bottom side 19. In the present example, conductor 44A is configured as a source electrode and conductor 46 is configured as a drain electrode. Conductor 44A and conductor 46 can comprise materials and characteristics as described previously and can be formed using processes as described previously.

In the present example, conductor 44B is provided over gate dielectric 26 and dielectric 260 within recess 180A and within recess 180B. In some examples, conductor 44B can comprise a doped polycrystalline material, such as doped polysilicon. In other examples, conductor 44B can comprise similar materials as described previously. In some examples, a dielectric 41 can be provided over conductor 44B. In some examples, dielectric 41 can comprise an oxide, such as a doped oxide. Semiconductor device 30B is an example of a semiconductor device comprising spacer-defined recesses 180A and 180B, which define JFET region 450.

FIG. 29 illustrates a partial cross-sectional view of semiconductor device 30C manufactured in accordance with the method described with FIGS. 24-26 after further processing. In the present example, semiconductor device 30C is configured as an accumulation mode FET (ACCUFET). In some examples, semiconductor device 30C is similar semiconductor device 30B and only differences are described hereinafter. In semiconductor device 30C, channel 45 comprises an accumulation channel and doped regions 37 are configured as body regions. In some examples, the width and doping concentration of channel 45 in semiconductor device 30C are preselected so that channel 45 is completely depleted because of a built-in potential that results from the MOS with material in region 44B having a relatively high work function. This causes a potential barrier between doped region 33 and a drift region 14 resulting in a normally-off device with the drain voltage supported by the drift region. With a positive gate voltage applied to conductor 44B, an accumulation of electrons at the interface between gate dielectric 26 and channel 45 forms providing a low resistance path for current flow through semiconductor device 30C. In some examples, doped region 37 can provide a shield for high SiC bulk electric field on gate dielectric 26/260. Semiconductor device 30C is an example of a semiconductor device comprising a spacer-defined recesses 180A and 180B, which define channel 45.

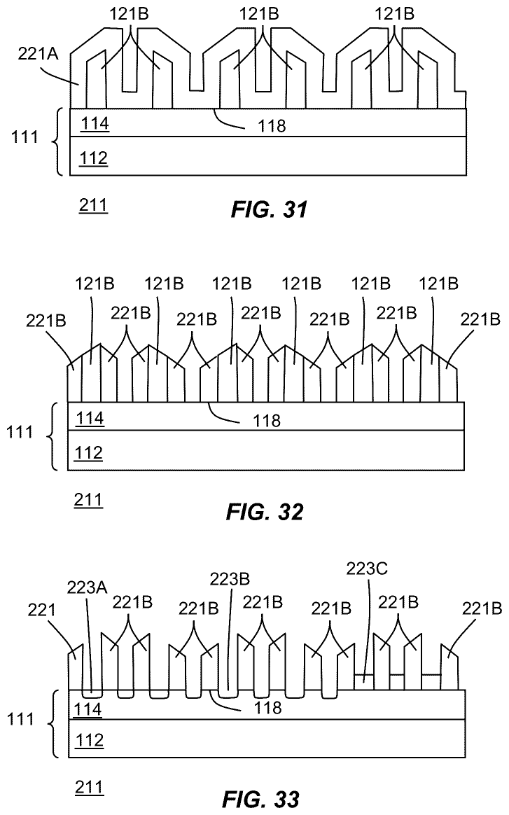

FIGS. 30, 31, 32, and 33 illustrate a partial cross-sectional view of a semiconductor device 211 at various steps in manufacture in accordance with the present description. The method provides regions for semiconductor device 211 that were previously limited by conventional lithography techniques for power semiconductor devices, such as SiC power devices. The method described in FIGS. 30-33 is an example method of forming spacers from other spacers.

With reference to FIG. 30, semiconductor device 211 can comprise body of semiconductor material 111, which in some examples, can comprise substrate 112 and semiconductor region 114 provided in or over substrate 112. In the present example, body of semiconductor material 111 includes a top side 118. Body of semiconductor material 111 can also comprise and can be referred to as a region of semiconductor material, a semiconductor workpiece, or a workpiece. In some examples, substrate 112 comprises a semiconductor substrate, such as a silicon or SiC substrate and semiconductor region 114 comprises an epitaxially formed region or a doped region. In some examples, substrate 112 and semiconductor region 114 are configured for manufacturing a power semiconductor device, such as a SiC power device. In the present example, the method described with FIGS. 1-4 can be used to provide first spacers 121B over top side 118 of body of semiconductor material 111. In other examples, body of semiconductor material 111 can comprise other semiconductor materials including silicon, IV-IV semiconductor materials (for example, SiGe, SiGeC), or compound semiconductor materials.

FIG. 31 illustrates semiconductor device 211 after further processing. In the present example, a conformal layer 221A is provided over top side 118 of body of semiconductor material 111 and first spacers 121B. In some examples, conformal layer 221A comprises a dielectric and can be formed using CVD techniques, such as LPCVD, PECVD, or other deposition techniques as known to one of ordinary skill in the art. In some examples, conformal layer 221A comprises an oxide, a nitride, or combinations thereof. The thickness of conformal layer 221A is selected in accordance with a desired lateral spacing between features, which will be provided self-aligned to second spacers subsequently formed from conformal layer 221A. The thickness of conformal layer 221A translates into the width of the second spacers. In some examples, the thickness of conformal layer 221A can be approximately 5000 Angstroms or less.

FIG. 32 illustrates semiconductor device 211 after further processing. In the present example, anisotropic etching can be used to remove portions of conformal layer 221A while leaving other portions of conformal layer 221A as spacers 221B along lateral sides of first spacers 121B. Spacers 221B can also be referred to or comprise spacer structures or second spacers. In some examples, dry etching techniques can be used to anisotropically etch conformal layer 221A to provide spacers 221B.

FIG. 33 illustrates semiconductor device 211 after further processing. In the present example, first spacers 121B are removed leaving second spacers 221B adjacent to top side 118 of body of semiconductor material 111. As described previously, second spacers 221B comprise a width set or defined by the thickness of the conformal layer used to form them. In subsequent processing, second spacers 221B can be used to form example features in or over body of semiconductor material 111. The features can include, but are not limited to, doped regions 223A, recesses or recessed regions 223B, or material regions 223C. In some examples, the features are formed self-aligned to two lateral sides of spacers 221B and are laterally separated by a distance determined by the width of second spacers 221B.

In some examples, the features for semiconductor device 211 provided using second spacers 221B can be the same, can be different, can be interconnected within body of semiconductor material 111, or can be isolated or discrete regions within body of semiconductor material 111. In some examples, the discrete regions can be subsequently coupled together using, for example, conductive interconnects. The method and features described herein can be used to form power semiconductor devices, such as SiC power devices.

In summary, structures and methods have been described for a semiconductor device having improved manufacturability and performance. More particularly, a method has been described that uses a spacer structure to define features of the semiconductor device that are laterally separated by distance defined by the spacer structure. The features include recesses and doped regions that are used to form, for example, gate regions or body regions for JFET semiconductor devices or IGFET semiconductor devices. In some examples, the semiconductor devices comprise SiC power semiconductor devices.

In some examples, the features can be provided as elongate stripe regions. In some examples, the features can be interconnected structures. In some examples, the features can be discrete or separated regions. In some examples, multiple spacer structures can be used to provide features having further reduced cell pitch.

Among other things, the spacer structures and methods described herein provide a cost-effective way to manufacture SiC power devices having reduced cell pitch without having to invest in very expensive photolithographic processing equipment. In some examples, the cell pitch can be reduced to less than two (2) microns compared to a pitch of greater than four (4) microns for previous devices. Accordingly, the methods and structures described provide semiconductor devices, such SiC power semiconductor devices with improved performance.

It is understood that the different examples described herein can be combined with any of the other examples described herein to obtain different embodiments.

While the subject matter of the invention is described with specific preferred examples, the foregoing drawings and descriptions thereof depict only typical examples of the subject matter and are not therefore to be considered limiting of its scope. It is evident that many alternatives and variations will be apparent to those skilled in the art. For example, the conductivity types of the various regions can be reversed. Also, other IV-IV semiconductor materials besides SiC, such as SiGe or SiGeC can be used. Additionally, other compound semiconductor materials can be used.

As the claims hereinafter reflect, inventive aspects may lie in less than all features of a single foregoing disclosed example. Thus, the hereinafter expressed claims are hereby expressly incorporated into this Description, with each claim standing on its own as a separate example of the invention. Furthermore, while some examples described herein include some, but not other features included in other examples, combinations of features of different examples are meant to be within the scope of the invention and meant to form different examples as would be understood by those skilled in the art.

What is claimed is:

1. A method of manufacturing a semiconductor device, comprising:
providing a body of semiconductor material comprising:
a top side;
a bottom side opposite to the top side; and
a first conductivity type;
providing a mask over the top side, the mask comprising a side wall;
providing a conformal layer over the top side and the mask;
removing a portion of the conformal layer to provide a first spacer adjoining the side wall of the mask;
removing the mask;
providing a first feature as a first part of the body of semiconductor material self-aligned to a first side of the first spacer;
providing a second feature as a second part of the body of semiconductor material self-aligned to a second side of the first spacer, wherein a portion of the body of semiconductor material is laterally interposed between the first feature and the second feature; and
removing the first spacer;
wherein:
the portion of the body of semiconductor material laterally interposed between the first feature and the second feature comprises a channel region of a JFET semiconductor device or a JFET region of an insulated gate field effect transistor device.

2. The method of claim 1, wherein:
providing the first feature comprises providing a first doped region comprising a second conductivity type opposite to the first conductivity type;
providing the second feature comprises providing a second doped region comprising the second conductivity type;
the portion of the body of semiconductor material laterally interposed between the first doped region and the second doped region comprises the channel region of the JFET semiconductor device; and
the first doped region and the second doped region provide a gate region for the JFET semiconductor device.

3. The method of claim 2, further comprising:
providing a third doped region comprising the first conductivity type coupled to the channel region.

4. The method of claim 3, wherein:
the channel region comprises a first elongate stripe;
the third doped region comprises a second elongate stripe; and
the second elongate stripe is generally orthogonal to the first elongate stripe in a top plan view.

5. The method of claim 4, wherein:
the gate region comprises third elongate stripes generally parallel to the first elongate stripe.

6. The method of claim 4, further comprising:
providing a fourth doped region comprising the second conductivity type coupled to the gate region;
wherein:
the fourth doped region comprises a fourth elongate stripe generally parallel to the second elongate stripe.

7. The method of claim 1, wherein:
providing the first feature comprises providing a first recess extending inward from the top side of the body of semiconductor material, the first recess comprising a first recess side wall and a first recess lower side; and
providing the second feature comprises providing a second recess extending inward from the top side of the semiconductor material, the second recess comprising a second recess side wall and a second recess lower side.

8. The method of claim 7, further comprising:
providing a first doped region comprising a second conductivity type extending into the body of semiconductor material from the first recess side wall and the first recess lower side;
providing a second doped region comprising the second conductivity type extending into the body of semiconductor material from the second recess side wall and the second recess lower side; and
providing a third doped region of the first conductivity type adjacent to the top side of the body of the semiconductor material;
wherein:
the portion of the body of semiconductor material laterally interposed between the first recess and the second recess comprises the channel region of the JFET semiconductor device;
the first doped region and the second doped region provide a gate region for the JFET semiconductor device; and
the third doped region provides a source region for the JFET semiconductor device.

9. The method of claim 7, further comprising:
providing a dielectric adjacent to the first recess side wall, the first recess lower side, the second recess side wall, and the second recess lower side;
providing a gate electrode within the first recess and the second recess adjacent to gate dielectric;
providing a first doped region comprising the first conductivity type adjacent to the top side of the body of semiconductor material and interposed between the first recess and the second recess; and
providing a second doped region comprising a second conductivity type opposite to the first conductivity type within the body of semiconductor material and comprising a first portion below the first recess lower side and a second portion below the second recess lower side.

10. The method of claim 9, further comprising:
providing a third doped region of the second conductivity type within the body of semiconductor material between the first recess and the second recess and adjoining the first doped region;
wherein:
the portion of the body of semiconductor material laterally interposed between the first recess and the second recess comprises the JFET region of the insulated gate field effect transistor device.

11. The method of claim 1, further comprising:
after providing the first feature and the second feature:
providing a second spacer structure comprising a second spacer first portion adjacent to a first side wall of the first spacer and a second spacer second portion adjacent to a second side wall of the first spacer;
removing the first spacer; and
providing an insulated gate structure proximate to the first feature and the second feature;
wherein:
the portion of the body of semiconductor material laterally interposed between the first feature and the second feature comprises the JFET region of the insulated gate field effect transistor device;
providing the first feature comprises providing a first doped region comprising a second conductivity type opposite to the first conductivity type;
providing the second feature comprises providing a second doped region comprising the second conductivity type; and
after providing the second spacer structure:
providing a third doped region of the first conductivity type in the first doped region self-aligned to the second spacer first portion; and
providing a fourth doped region of the first conductivity type in the second doped region self-aligned to the second spacer second portion.

12. The method of claim 1, wherein:
providing the body of semiconductor material comprises providing a IV-IV semiconductor material.

13. A method of manufacturing a power semiconductor device, comprising:
providing a body of semiconductor material comprising:
a top side;
a bottom side opposite to the top side;
a SiC semiconductor material; and
a first conductivity type;
providing a first spacer over the top side; and
providing a first doped region and a second doped region both comprising a second conductivity type opposite the first conductivity type self-aligned to the first spacer, wherein the first doped region and the second doped region are laterally spaced apart to define a channel region between the first doped region and the second doped region.

14. The method of claim 13, further comprising:
providing a third doped region of the first conductivity type coupled to the channel region; and
providing a fourth doped region of the second conductivity type coupled to the first doped region and the second doped region, wherein:
providing the first spacer comprises:
providing a mask over the top side, the mask comprising a side wall;
providing a conformal layer over the top side and the mask;
removing a portion of the conformal layer to provide the first spacer adjoining the side wall of the mask; and
removing the mask.

15. The method of claim 14, further comprising:
providing a first conductor coupled to the third doped region;
providing a second conductor coupled to the fourth doped region; and
providing a third conductor coupled to the bottom side of the body of semiconductor material.

16. The method of claim 14, wherein:
providing the first doped region and the second doped region comprises providing a gate structure;
the channel region comprises a first elongate stripe;
the third doped region comprises a second elongate stripe generally perpendicular to the first elongate stripe;
the gate structure comprises third elongate stripes generally parallel to the first elongate stripe; and
the fourth doped region comprises a fourth elongate stripe generally parallel to the second elongate stripe.

17. A method of manufacturing a semiconductor device, comprising:
providing a body of semiconductor material comprising:
a substrate;
a semiconductor region over the substrate comprising a first conductivity type;
a top side;
a bottom side opposite to the top side; and
the first conductivity type;
providing a first spacer over the top side;
providing a first feature as part of the body of semiconductor material self-aligned to a first side wall of the first spacer; and
providing a second feature as part of the body of semiconductor material self-aligned to a second side wall of the first spacer;
wherein:
a portion of the semiconductor region is laterally interposed between the first feature and the second feature;
the first feature comprises a first doped region or a first recess;
the second feature comprises a second doped region or a second recess; and
the portion of the semiconductor region laterally interposed between the first feature and the second feature comprises a channel region of a JFET semiconductor device or a JFET region of an insulated gate field effect transistor device.

18. The method of claim 17, wherein:
providing the first feature comprise providing the first doped region comprising a second conductivity type opposite to the first conductivity type;
providing the second feature comprises providing the second doped region comprising the second conductivity type;
the first doped region and the second doped region comprise a gate region;
the portion of the semiconductor region interposed between the first doped region and the second doped region comprises the channel region; and
the channel region comprises a first elongate stripe region.

19. The method of claim 17, wherein:
providing the first feature comprises providing the first recess extending inward from the top side of the body of semiconductor material, the first recess comprising a first recess side wall and a first recess lower side; and
providing the second feature comprises providing the second recess extending inward from the top side of the semiconductor material, the second recess comprising a second recess side wall and a second recess lower side.

20. The method of claim 19, further comprising:
providing a dielectric adjacent to the first recess side wall, the first recess lower side, the second recess side wall, and the second recess lower side;
providing a gate electrode within the first recess and the second recess adjacent to gate dielectric;
providing a third doped region comprising the first conductivity type adjacent to the top side of the body of semiconductor material and interposed between the first recess and the second recess; and
providing a fourth doped region comprising a second conductivity type opposite to the first conductivity type within the body of semiconductor material and comprising a first portion below the first recess lower side and a second portion below the second recess lower side.
